(19) United States
(12) Patent Application Publication
(10) Pub. No.: US 2006/0076647 A1
(43) Pub. Date: Apr. 13, 2006

(54) Semiconductor component with a bipolar lateral power transistor

(75) Inventors: Axel Naethe, Hamburg (DE); Juergen Kordts, Buxtehude (DE); Ralf Beier, Hamburg (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS, N.V., EINDHOVEN THE NETERLANDS (NL)

(21) Appl. No.: 10/537,924

(22) PCT Filed: Dec. 8, 2003
(86) PCT No.: PCT/IB03/05860

§ 371 Date: Jun. 7, 2005

(30) Foreign Application Priority Data
Dec. 11, 2002 (EP) 02102731.3

(51) Int. Cl. H01L 27/082

(52) U.S. Cl. 257/573; 257/575; 257/576; 257/578

(57) ABSTRACT

A semiconductor component comprising at least one lateral bipolar power transistor which is composed of at least one group of single transistors with a common collector-, base- and emitter zone, which are parallel connected by three conductor track systems which bring together the emitter-, base- and collector currents of each of the single transistors; and each single transistor comprises an emitter region having an emitter-contact zone with an emitter contact, at least one active emitter zone and a connection zone between the contact zone and the active zone, a base region having a base-contact zone with a base contact and an internal base series resistor, and a collector region, said internal base series resistor being a structured semiconductor region comprising at least two ring segments, which is connected to the base contact zone and to the base contact.

The invention relates to a semiconductor component, in particular of the planar-epitaxial type, comprising at least one bipolar lateral power transistor which is composed of a group of single transistors having a common collector-, base- and emitter zone, which are parallel connected by three conductor track systems. Said three conductor track systems bring together the emitter-, base- and collector currents of each of the single transistors. Each single transistor comprises an emitter region having an emitter-contact zone with an emitter contact and at least one active emitter zone, a base region having a base-contact zone with a base contact, an active base zone and an internal base series resistor, and a collector region.

Bipolar power transistors are customarily composed of multiple parallel-integrated single transistors which are provided with finger-shaped conductor tracks. For this reason, these power transistors are also referred to as multi-finger transistors. By joining them together, a higher output current as compared to single transistors is obtained.

Such bipolar power transistors are very robust per se. This is, for example, ultimately the reason why bipolar power transistors are used in analog amplifiers, peripheral data devices, electromedicine, electric vehicles, for motor ignition and motor control, for interruption-free power supply, for switched-mode mains power supply and TV deflection circuits.

However, such power transistors must cope with substantial load currents. These load currents generate a voltage drop as well as heat in the component. Due to the heat generation directly associated with a power load on the transistor and the resultant temperature increase, the loadability of a power transistor is limited.

This can be attributed to the fact that as a result of a local temperature increase of the emitter-base junction, an increase of the emitter current at the emitter base junction takes place at the location where such a temperature increase, even if it is only small, occurs. This leads to a local increase in power dissipation and hence to a further temperature rise. In this manner, an avalanche effect may develop which leads to breakdown.

A substantial local heat release as a result of short time loading outside the permissible range generally does not lead to permanent damage, however, overloading for a longer period of time may cause irreversible damage to the transistor. This may lead to breakdown of the component.

To preclude said local temperature increase, the so-termed “second breakdown”, power transistors are often provided with resistors in the emitter or base contact.

If resistors are provided, for example, in the emitter path of the transistor, which resistors are connected to the emitter fingers, it is achieved that in the event of a local temperature increase and the current increase primarily associated therewith, the forward voltage at the emitter-base junction and hence the emitter current at this emitter base junction is reduced.

DE 3035462 discloses a semiconductor element comprising at least one bipolar power transistor with parallel-connected transistor regions and with base subregions, wherein, between active base regions at the emitter-base pn junction and contacted base regions resistors, so-termed base series resistors, are provided, and the base current largely flows through the base series resistors, and the voltage drop across the emitter region is small as compared to the voltage between the active base region and the contacted base region.

To achieve substantially complete protection against “second breakdown” for the entire range in which operation of the transistor must be possible, comparatively high base series resistors with corresponding isolation are required. Frequently, however, the operating conditions are such that much lower resistance values are also sufficient, as is the case when a large current is required and, at the same time, a small voltage drop at the resistor. In general it can thus be said that the selection of specific resistance values in view of specific operating conditions of the transistor cannot guarantee optimum functioning of the transistor under other operating conditions.

It is an object of the invention to provide, inter alia, a semiconductor component with a power transistor of the type under consideration, which exhibits a high thermal loadability, particularly in virtue of a homogenization of the field variation, and a simple structure.

In accordance with the invention, this object is achieved by a semiconductor component comprising at least one lateral bipolar power transistor which is composed of at least one group of single transistors with a common collector-, base- and emitter zone, which are parallel connected by three conductor tracks systems which bring together the emitter-, base- and collector currents of each of the single transistors; and each single transistor comprises an emitter region having an emitter-contact zone with an emitter contact, at least one active emitter zone and a connection zone between the contact zone and the active zone, a base region having a base-contact zone with a base contact and an internal base series resistor, and a collector region, said internal base series resistor being a strictured semiconductor region comprised of at least two ring segments, which is connected to the base contact zone and the base contact.

By virtue of the internal base series resistor, a homogenization of the field strength and current variation is achieved. The integrated internal base series resistors generate a negative feedback which brings about a uniform current distribution in the power transistor. An impermissible temperature increase in the center of the power transistor is thus precluded.

In accordance with a preferred embodiment of the invention, the internal base series resistor is a structured semiconductor region with emitter doping.

By virtue of the higher positive temperature coefficient (PTC) of a base series resistor with emitter doping, as compared to the base region, the risk of a hot spot is reduced in that, at the hotter spots, the base current negative feedback rises relative to the cooler spots and the current at the hotter locations is reduced.

Particular advantages as compared to the prior art are obtained by means of the invention when the overlay region between the base conductor track system and the base series resistor is minimized.

Within the scope of the invention it is further preferred that the conductor track systems are formed by a single layer metallization.

In the case of a single layer metallization, the emitter cannot be connected everywhere to the emitter conductor track system, particularly not below the conductor track system of the individual base regions. As the non-contacted emitter region has a higher impedance value, it acts as an additional, negative-feedback emitter resistor.

These and other aspects of the invention are apparent from and will be elucidated with reference to the embodiments described hereinafter.

In the drawings:

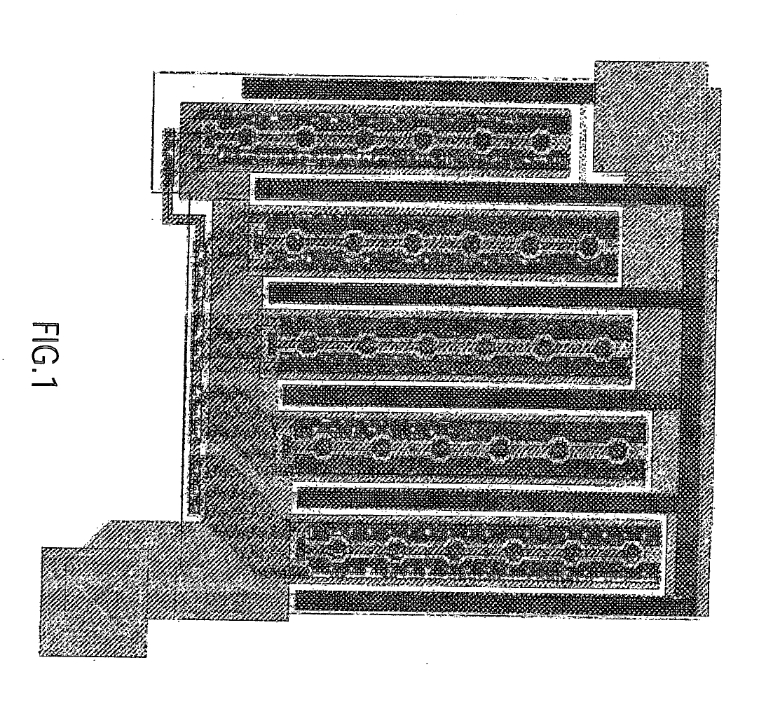

FIG. 1 is a plan view of an example of a semiconductor component with power transistors in accordance with the invention,

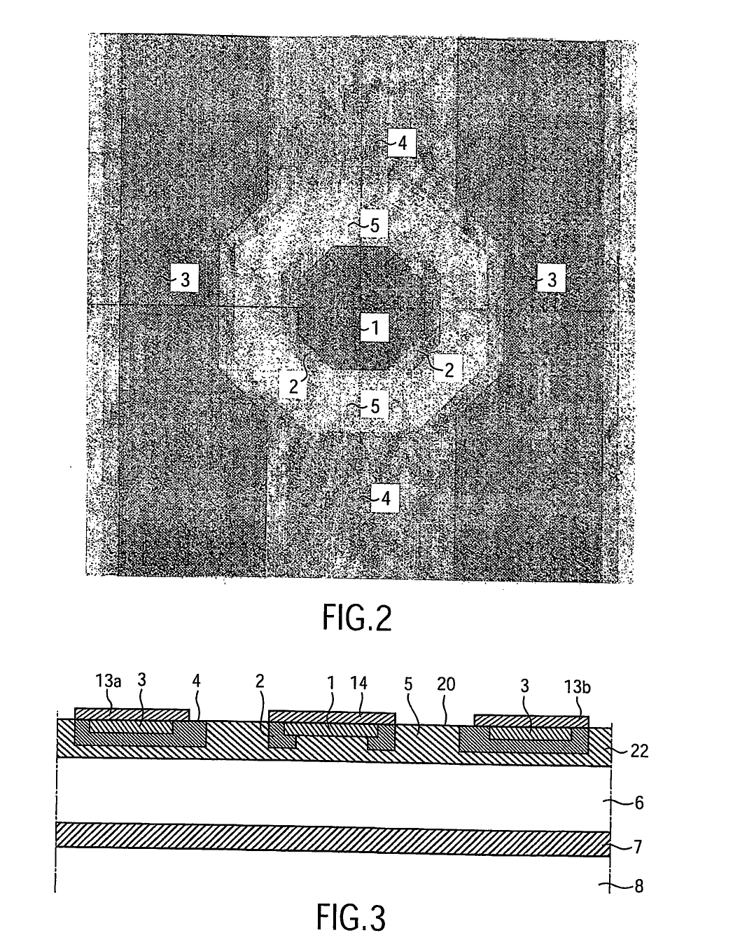

FIG. 2 is a plan view of a section of a power transistor shown in FIG. 1,

FIG. 3 is a cross-sectional view of the power transistor shown in FIG. 1.

The semiconductor component comprises a power transistor which is embodied so as to be a lateral bipolar transistor, preferably of the planar-epitaxial type.

Said power transistor comprises a group of single transistors having a common collector-, base- and emitter zone, which are parallel-connected by three conductor track systems which interconnect the respective emitter-, base- and collector zones of the single transistors.

Each single transistor has an emitter region comprising an emitter contact zone with an emitter contact and at least one active emitter zone.

Each single transistor also has abase region comprising abase contact zone with a base contact, at least one active base zone and a connection zone between the contact zone and the active zone.

Each single transistor further comprises a collector region.

As shown in FIG. 3, the semiconductor component of the planar-epitaxial type is composed of a semiconductor body with a substrate 8 on which an epitaxial layer 6 is grown. In the part of the semiconductor component under consideration here, a buried, properly conducting layer 7 is generated in a customary manner between the substrate and the epitaxial layer.

The epitaxial layer is customarily sealed from the surroundings by means of a deep isolation diffusion and thus forms the well that accommodates the lateral bipolar power transistor.

For the collector, conductive contact zones are formed in the epitaxial layer by collector deep diffusion regions indiffused from the surface, which contact zones project into the buried layer 7 and bound a long stretched-out finger-shaped collector zone which is contacted via these contact zones.

In the collector region there is a base zone for each single transistor, and in the base zone there is an emitter zone 3, 4 at the surface.

As shown in the plan view of FIG. 1, the active emitter zones of the single transistors are arranged such that in each emitter finger there is a sequence of equal, successive structures which each form a single transistor. In each one of these single transistors, the emitter zone comprises an active emitter zone 4 and an emitter contact zone 3.

In the emitter region 3, 4, at the surface thereof, there is a contacted base region 5. Said contacted base contact region 5 is centrally arranged, and annularly encloses the emitter region 4 and laterally bounds the emitter contact region 3. Said emitter region 3, 4 is in turn surrounded by a non-contacted base region 22.

The connection between the non-contacted base region 22 and the contacted base region 2 is partly interrupted by series resistors 2. Said series resistors are arranged as ring segments between the contacted base region 2 and the contacted emitter region 3.

For this purpose, between the contacted emitter region 3 and the contacted base region 5, a segmented ring-shaped region 2 is provided, which generally has the same doping as the emitter, yet is connected to the base potential. The base region is constricted by the segmented ring-shaped region 2.

The constricted base regions below the ring-shaped region 2 form the actual base series resistors.

Each base series resistor 2 is divided into two ring segments by two parting lines arranged preferably in the circumferential direction at distances of 180°. Each ring segment can also be provided, at its free end facing away from the base contact, with a conical taper (bevel).

In accordance with a preferred embodiment of the invention, the parting lines are arranged underneath the conductor track that interconnects the base zones. Preferably, the width of the parting lines is larger than or equal to the width of the base conductor track.

For this purpose, the parting lines have at least a width that corresponds to the width of the base conductor track, so that the overlay region between the base conductor track system and the base series resistor is minimized.

The concrete shape of the ring segments and the parting lines is to be determined by the person skilled in the art. It is essential that, in accordance with the invention, an embodiment of a base series resistor comprising at least two ring segments is provided, said individual, adjacent ring segments preferably being situated, viewed in projection, on either side of the base conductor track.

For the purpose of providing isolation between the individual transistor regions and the superjacent conductor track systems for base, emitter and collector, which are necessary for establishing the connection, one or more isolating layers are deposited on the upper main surface 20, which layers are not shown in FIG. 3 for clarity.

Via the apertures in the isolating layer, the emitter contact zone, the base contact zone and the base series resistor as well as the collector are connected to the reference potential via the respective conductor tracks. Particularly for contacting the base contact region 5 and the base series resistors 2, the contact windows 1 are provided. Said contact windows form common contact windows for the base metallization and for the metallization of the series resistors.

Contacting of the base region 2 is effected by the base conductor track 14. Between the non-contacted base region 22 and the surface 20 there is the emitter region 1. Said emitter region 1 is contacted by the emitter conductor track system 13, which is customarily divided into two fingers 13a, 13b. To contact the collector deep-diffusion regions 5, collector conductor tracks are additionally provided.

For the collector terminal, use can also be made of a metallization on an isolating layer present on the lower principal surface of the substrate.

The necessary electric connections between and to the single transistors and the contacts are preferably formed from a single, originally contiguous metallization layer that is deposited on the passivation layer.

The comb-shaped conductor track systems, which together with the contacts provide the desired interconnections, are formed from the metallization layer. This requires only a single metallization level.

In the case of discrete power transistors, the same structure as that shown in FIG. 1 can be formed, with this difference that collector deep diffusions are dispensed with.

The planar bipolar transistors in accordance with the invention can be manufactured, for example, by means of the standard method of manufacturing bipolar transistors, i.e. the SBC technique (Standard Buried Collector technique). Alternatively use can be made of the isoplanar technique.

In accordance with a preferred embodiment of the invention, the lateral bipolar transistor is an npn power transistor comprising an emitter zone 3, 4 of the n-conductivity type, a base zone 5 of the p-conductivity type and a collector zone of the n-conductivity type.

The starting material used for an npn power transistor in accordance with the invention is a p-conductive silicon chip wherein a buried, heavily doped n⁺ layer is indiffused at locations where transistors are formed at a later stage. Subsequently, a thin, n-doped epitaxial layer having a thickness in the range of 2 to 18 μm is grown. By means of p-type deep diffusion said epitaxial layer is divided into isolated regions.

The buried layer 7 of the n-conductivity type serves to connect the collector zone 6 of the npn transistor in a low-impedance manner. The buried layer 7 extends parallel to the semiconductor surface. A semiconductor zone of the n-conductivity type extending from the semiconductor surface up to the buried layer 7 also serves to connect the collector zone of the npn transistor in a low-impedance manner. The npn transistor is separated from other components, not shown in FIG. 1, by a separation zone of the p-conductivity type.

Next, in two further doping steps, the epitaxial layer for the base is p-doped and the epitaxial layer for the flat emitter is n-doped. As a result, planar npn transistors are obtained. Thus, barrier layer isolation is employed here to isolate the collector regions.

The diffusion regions 4 structured so as to form ring segments are arranged in the base region 2. These diffusion regions 4 form the internal base series resistor. The doping type of these diffusion regions 4 is the same as that of the emitter region 3. The diffusion regions 4 can thus be manufactured simultaneously with the emitter region 3. Consequently, the diffusion regions 4 can be manufactured without additional technology steps.

The base series resistor 2 is formed by two sub-zones situated between base zone 5 and contact 1, in particular underneath the base conductor track 14. The size of the base series resistor is set by the dimensioning of the diffusion zone. The dimensioning of the diffusion zone of the emitter as well as the location of the contacts 3 is also of ( in general secondary) importance.

Finally, the surface of the semiconductor body is provided with an isolation layer that is structured such that the contact zones can be connected. For this purpose, contact apertures are formed in the isolation layer, which accommodate metallic contacts forming the connection to the conductor track systems. For the conductor track systems, preferably, a single layer metallization is provided. To this end, a thin, closed metal layer is provided by evaporation, and is subsequently structured by means of photolithography.

Power transistors in accordance with the invention can be very advantageously used for applications in the low and medium frequency range.

1. A semiconductor component comprising at least one lateral bipolar power transistor which is composed of at least one group of single transistors with a common collector-, base- and emitter zone, which are parallel connected by three conductor track systems which bring together the emitter-, base- and collector currents of each of the single transistors; and each single transistor comprises an emitter region having an emitter-contact zone with an emitter contact, at least one active emitter zone and a connection zone between the contact zone and the active zone, a base region having a base-contact zone with a base contact and an internal base series resistor, and a collector region, characterized in that said internal base series resistor is a structured semiconductor region comprised of at least two ring segments, which is connected to the base-contact zone and the base contact.

2. A semiconductor component as claimed in claim 1, characterized in that the internal base series resistor is a structured semiconductor region with emitter doping.

3. A semiconductor component as claimed in claim 1, characterized in that the overlay region between the base conductor track system and the base series resistor is minimized.

4. A semiconductor component as claimed in claim 1, characterized in that the conductor track systems are formed by a single layer metallization.
